(19) United States
(12) Patent Application Publication
(10) Pub. No.: US 2022/0015265 A1
(43) Pub. Date: Jan. 13, 2022

(54) VAPOR CHAMBER

(71) Applicant: AURAS TECHNOLOGY CO., LTD., New Taipei City (TW)

(72) Inventors: Chih-Wei Chen, New Taipei City (TW); Tien-Yao Chang, New Taipei City (TW); Che-Wei Kuo, New Taipei City (TW); Hsiang-Chih Chuang, New Taipei City (TW)

(21) Appl. No.: 17/075,839

(22) Filed: Oct. 21, 2020

(30) Foreign Application Priority Data
Jul. 8, 2020 (TW) 109123062

(51) Int. Cl. H05K 7/20

(52) U.S. Cl. CPC H05K 7/20309; H05K 7/20318; H05K 7/20327

(57) ABSTRACT

A vapor chamber is provided, which includes: a substrate; a diversion layer disposed on the substrate and having first openings and second openings; and at least one liquid passage formed between the substrate and the diversion layer, where the vapor chamber is defined with an evaporation area corresponding to a heat source and at least one condensation area, and the size of the first openings corresponding to the evaporation area and the condensation area is different from the size of the second openings corresponding to a non-evaporation area and a non-condensation area.

### BACKGROUND

### 1. Technical Field

The present disclosure generally relates to the field of heat dissipation. More specifically, the present disclosure relates to a vapor chamber.

### 2. Description of Related Art

In the face of modernization, computers and various other electronic devices have seen rapid developments and improved performance. However, along with these improvements, heat dissipation has become one of the major problems faced by high performance hardware today. Typically, computers and electronic devices employ heat dissipating components to help dissipate heat away. For example, a heat dissipating gel or a heat dissipating sheet can be attached onto an electronic component that is subjected to heat dissipation in order to absorb and disperse heat. However, this type of heat dissipation has limited effect. As a result, phase changes of a working fluid have thus been taken advantage of so as to promote heat transfer of the heat dissipating components.

Heat transfer is achieved in the above heat dissipating components through phase changes and the direction of the flow of the working fluid. For example, the direction of the flow of a working fluid on capillary structures is opposite to the direction of a vapor flow formed from the working fluid that has been turned into vapors, and the directions of the flows form a circulating loop. However, in the existing heat dissipating components, the working fluid and the vapor flow flowing in the same channel space tend to interfere with each other. For example, when the shear stress of the vapor flow is larger than the surface tension of the working fluid, working fluid at the interface may become scattered, or the working fluid may even flow in reverse as it is accompanied by the vapor flow, resulting in poor heat transfer efficiency.

Therefore, there is a need to provide a vapor chamber that effectively addresses the aforementioned shortcomings of the prior art.

### SUMMARY

An objective of the present disclosure is to provide a vapor chamber defined with an evaporation area corresponding to a heat source and at least one condensation area, the vapor chamber including: a first substrate; a diversion layer disposed on the first substrate and having a plurality of first openings and a plurality of second openings, wherein locations of the plurality of first openings correspond to the evaporation area and the condensation area, locations of the plurality of second openings do not correspond to the evaporation area and the condensation area, and a size of the plurality of first openings is different from a size of the plurality of second openings; a plurality of liquid passages formed between the first substrate and the diversion layer; and a second substrate disposed above the diversion layer to form air flow channels between the diversion layer and the second substrate.

In the vapor chamber above, a density of the plurality of first openings is greater than a density of the plurality of second openings.

In the vapor chamber above, a ratio of an aperture of each of the plurality of first openings to an interval between the plurality of first openings is 1:1.

In the vapor chamber above, a ratio of an aperture of each of the plurality of second openings to an interval between the plurality of second openings ranges from 1:2 to 1:4.

In the vapor chamber above, the size of the plurality of first openings is greater than the size of the plurality of second openings.

In the vapor chamber above, an aperture of the plurality of first openings ranges from 0.01 mm to 0.3 mm, and an aperture of the plurality of second openings ranges from 0.005 mm to 0.2 mm.

In the vapor chamber above, the plurality of liquid passages are a plurality of grooves recessed into a surface of the first substrate, or a particle-sintered mass, a metal mesh or a combination of the above.

In the vapor chamber above, a width of each of the plurality of grooves ranges from 0.03 mm to 0.3 mm, and wherein a depth of each of the plurality of grooves ranges from 0.01 mm to 0.15 mm.

In the vapor chamber above, the plurality of grooves are formed by wet etching.

In the vapor chamber above, the plurality of grooves have elongated, curved, square or directional shapes.

In the vapor chamber above, the directional shape includes a width of a portion corresponding to the condensation area being greater than a width of a portion corresponding to the evaporation area.

In the vapor chamber above, a thickness of the diversion layer ranges from 0.005 mm to 0.05 mm.

The vapor chamber above further includes at least one thin film layer with a plurality of through holes and disposed between the diversion layer and the first substrate, wherein a size of the plurality of through holes corresponding to the locations of the plurality of first openings is greater than the size of the corresponding plurality of first openings.

The vapor chamber above further includes a plurality of thin film layers stacked one on top of another between the first substrate and the diversion layer, wherein the plurality of thin film layers each includes a plurality of through holes, and the plurality of through holes of one of the plurality of thin film layers are not entirely in alignment with the plurality of through holes of another one of the plurality of thin film layers.

In the vapor chamber above, the plurality of through holes are crisscross-shaped, triangular, star-shaped, regular polygonal or irregular polygonal.

The vapor chamber above further includes at least one thin film layer disposed between the diversion layer and the second substrate and in contact with the diversion layer and the second substrate, wherein the air flow channels are provided within the thin film layer.

The vapor chamber above further includes a working fluid filled in the plurality of liquid passages, wherein the working fluid absorbs heat from the heat source and then vaporizes in the evaporation area, the vaporized working fluid then passes through each of the first openings corresponding to the evaporation area and moves along the air flow channels to the condensation area, the working fluid then condenses and liquefies in the condensation area, and the liquefied working fluid passes through each of the first openings corresponding to the condensation area and flows along the plurality of liquid passages to return to the evaporation area.

### BRIEF DESCRIPTION OF THE DRAWINGS

FIG. 1A is a schematic view of a vapor chamber in accordance with the present disclosure in use.

FIG. 1B is a schematic exploded view of the vapor chamber in accordance with the present disclosure.

FIG. 2 is a schematic cross-sectional view of the vapor chamber in accordance with the present disclosure.

FIG. 3 is a schematic view depicting a surface of a diversion layer in the vapor chamber in accordance with the present disclosure.

FIG. 4 is a schematic view depicting first openings of the diversion layer in the vapor chamber in accordance with an implementation of the present disclosure.

FIG. 5 is a schematic view depicting second openings of the diversion layer in the vapor chamber in accordance with an implementation of the present disclosure.

FIGS. 6A and 6B are schematic partial top views of liquid passages in the vapor chamber in accordance with different embodiments of the present disclosure.

FIG. 7 is a schematic cross-sectional view of a vapor chamber in accordance with another embodiment of the present disclosure.

FIG. 8A is a schematic exploded view depicting a plurality of thin film layer in a vapor chamber in accordance with an embodiment of the present disclosure.

FIGS. 8B and 8C are schematic views depicting through holes of the plurality of thin film layers in the vapor chamber of the present disclosure before and after stacking.

FIG. 9A is a schematic cross-sectional view of a vapor chamber in accordance with yet another embodiment of the present disclosure.

FIG. 9B is a schematic top view of a thin film layer shown in FIG. 9A.

### DETAILED DESCRIPTION

Embodiments of the present disclosure are illustrated with specific implementations. Other advantages and technical effects of the present disclosure can be readily understood by one with ordinary skills in the art upon reading the disclosure provided herein, and can be used or applied in other different implementations.

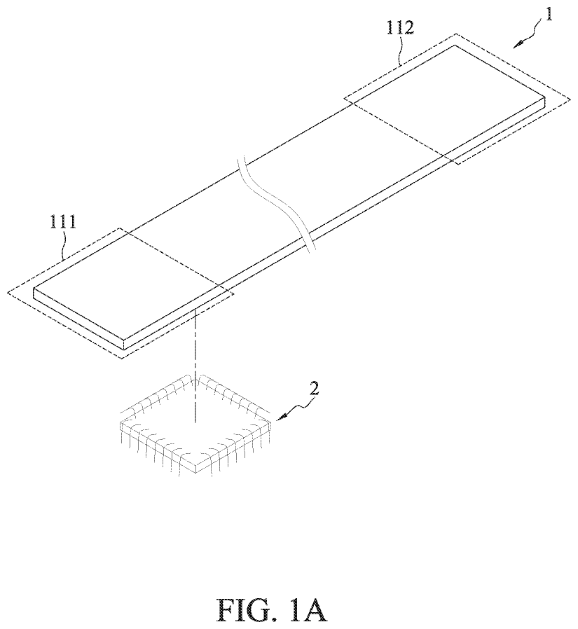

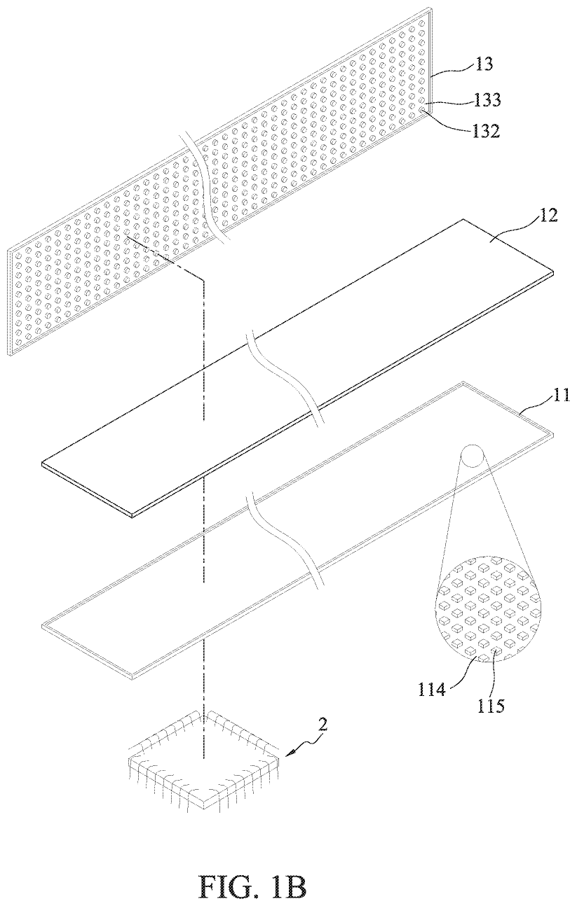

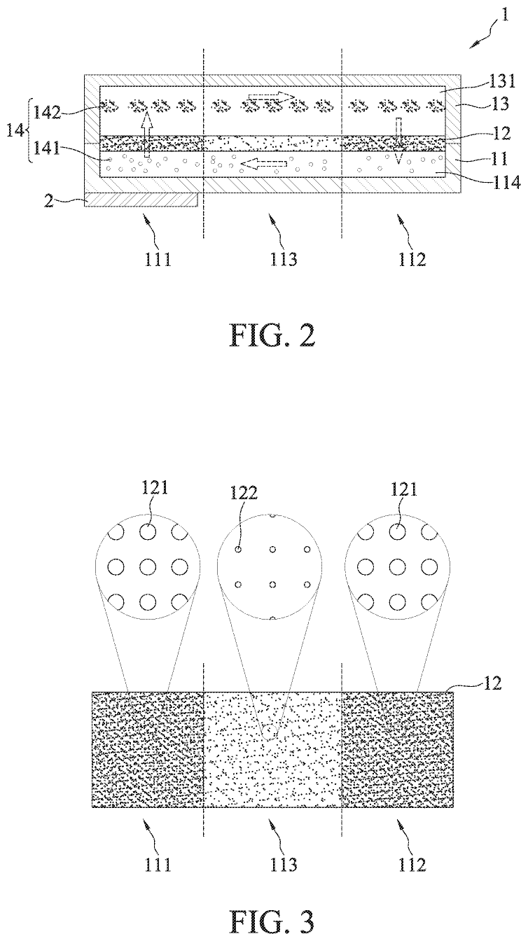

Referring to FIGS. 1A, 1B, 2 and 3, a vapor chamber 1 of the present disclosure includes a first substrate 11, a diversion layer 12 and a second substrate 13. The vapor chamber 1 of the present disclosure can be in contact with at least one heat source 2, and the vapor chamber 1 is defined with an evaporation area 111 corresponding to the heat source 2 and at least one condensation area 112, and a heat insulation area 113 other than the evaporation area 111 and the condensation area 112. The following descriptions are discussed using one heat source 2, one evaporation area 111, one condensation area 112 and one heat insulation area 113 as an example, but the present disclosure is not limited as such. It should first be noted that columns 115 and support columns 132 shown in FIG. 1B are omitted in FIG. 2 in order to clearly illustrate the flow direction of the working fluid 14.

A plurality of liquid passages 114 can be formed between the first substrate 11 and the diversion layer 12 to be filled with the working fluid 14. In an embodiment, the liquid passages 114 can be formed from a particle-sintered mass, a metal mesh, grooves or a combination of the above, wherein the particle-sintered mass refers to constructions or structures with multiple capillary holes or interconnected holes formed by sintering of metal powder, and the metal mesh refers to a mesh with multiples openings woven using metal. In addition, as shown in FIG. 1B, the grooves refer to a plurality of interconnected grooves formed from gaps between a plurality of columns 115 produced on the surface of the first substrate 11 by wet etching, such that the working fluid 14 can be filled therein.

In an embodiment, the width of the grooves (i.e., the gaps between the columns 115) ranges from 0.03 mm to 0.3 mm, and the depth of the grooves (i.e., the height of each of the columns 115 or the depth from the surface of the first substrate 11) ranges from 0.01 mm to 0.15 mm. However, the present disclosure is not limited to these, and the present disclosure does not limit the number of grooves (i.e., the number of columns).

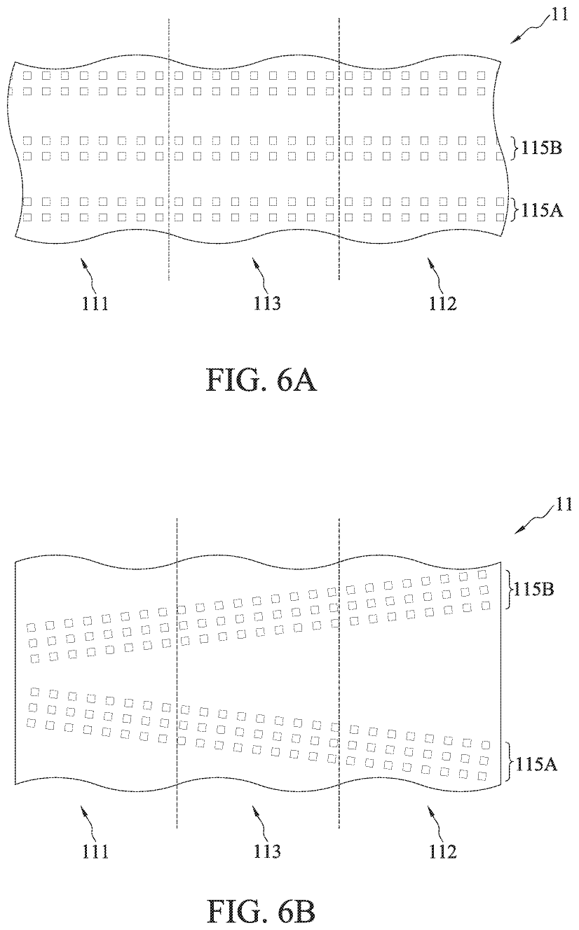

In another embodiment, depending on the needs, the vapor chamber 1 of the present disclosure may simultaneously include grooves of different widths and depths. For example, the majority of the grooves have a smaller width (e.g., between 0.05 and 0.1 mm), while one particular groove has a larger width (e.g., between 0.1 and 0.5 mm), so that the larger-width groove can accommodate more working fluid 14, while the smaller-width grooves can be used to provide greater capillary forces, improving transmission performance. As shown in FIG. 6A, the width among columns 115A (or columns 115B) is smaller compared to the width between the columns 115A and the columns 115B.

In yet another embodiment, the widths and depths of the grooves may vary depending on the total thickness of the first substrate 11. For example, when the total thickness of the first substrate 11 is between 0.05 mm and 0.1 mm, the width of the grooves may be between 0.05 mm and 0.2 mm, and the depth may be between 0.03 mm and 0.08 mm. When the total thickness of the first substrate 11 is between 0.12 mm and 0.2 mm, the width of the grooves may be between 0.08 mm and 0.3 mm, and the depth may be between 0.05 mm and 0.15 mm. When the total thickness of the first substrate 11 is between 0.02 mm and 0.05 mm, the width of the grooves may be between 0.03 mm and 0.1 mm, and the depth may be between 0.01 mm and 0.04 mm. However, the present disclosure is not limited to the aforementioned ranges of the total thicknesses of the first substrate 11 and the widths and depths of the grooves.

In still another embodiment, the liquid passages 114 may be realized in different embodiments. As shown in FIG. 6B, the liquid passages 114 can also be configured with a directional shape, such as a trapezoid, that is, the width of a portion of the liquid passages 114 (the width between a portion of the columns 115A and the columns 115B) corresponding to the condensation area 112 is greater than the width of another portion of the liquid passages 114 (the width between another portion of the columns 115A and the columns 115B) corresponding to the evaporation area 111, facilitating the flow of the working fluid 14 at the condensation area 112 towards the evaporation area 111. Moreover, the liquid passages 114 may be elongated, curved, square, etc., by simply allocating the columns 115 in different arrangements. However, the present disclosure is not limited as such.

The diversion layer 12 is provided on the first substrate 11 and the liquid passages 114 and includes a plurality of first openings 121 and a plurality of second openings 122. The first openings 121 and the second openings 122 both penetrate through the two surfaces of the diversion layer 12. In an embodiment, the first openings 121 and the second openings 122 are formed by processes such as etching, laser engraving, stamping, etc., such that the diversion layer 12 is formed into a meshed structure, but the present disclosure is not limited as such. Moreover, the locations of the first openings 121 correspond to the evaporation area 111 and the condensation area 112, whereas the locations of the second openings 122 correspond to the heat insulation area 113, in other words, the second openings 122 are not located in the evaporation area 111 and the condensation area 112. Furthermore, the size (aperture) of the first openings 121 is different from the size (aperture) of the second openings 122.

In an embodiment, the size (aperture) of the first openings 121 is greater than the size (aperture) of the second openings 122. For example, the aperture of the first openings 121 may range from 0.01 mm to 0.3 mm, and the aperture of the second openings 122 may range from 0.005 mm to 0.2 mm, such that the first openings 121 are air and water permeable, whereas the second openings 122 are air permeable but not water permeable. However, the present disclosure is not limited as such. In addition, the thickness of the diversion layer 12 may range from 0.005 mm to 0.05 mm, preferably less than 0.025 mm, but the present disclosure is not limited to these.

In an embodiment, the density of the first openings 121 on the first substrate 11 can be greater than the density of the second openings 122 on the first substrate 11. For example, the density of the first openings 121 corresponding to the evaporation area 111 can be greater than the density of the second openings 122 corresponding to the heat insulation area 113. Furthermore, the densities of the first openings 121 corresponding to the evaporation area 111 and the condensation area 112 can both be greater than the density of the second openings 122 corresponding to the heat insulation area 113, or the density of the first openings 121 corresponding to only one of the evaporation area 111 and the condensation area 112 is greater than the density of the second openings 122 corresponding to the heat insulation area 113, and the present disclosure is not limited as such.

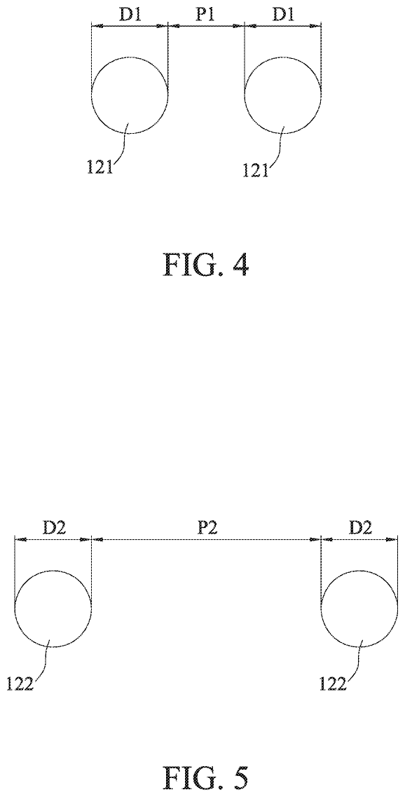

Referring to FIG. 4, the density of the first openings 121 can be determined by the aperture of the first openings 121 and the interval between the first openings 121. For example, the ratio of the aperture D1 of the first openings 121 to the interval P1 between the first openings 121 is 1:1, and the present disclosure is not limited to this.

Referring to FIG. 5, the density of the second openings 122 can be determined by the aperture of the second openings 122 and the interval between the second openings 122. For example, the ratio of the aperture D2 of the second openings 122 to the interval P2 between the second openings 122 ranges from 1:2 to 1:4, and the present disclosure is not limited to these.

The second substrate 13 is disposed on the diversion layer 12, and a plurality of support columns 132 are formed on an inner surface 133 of the second substrate 13, such that air flow channels 131 are formed between each of the support columns 132 of the second substrate 13 and the diversion layer 12. In an embodiment, as shown in FIGS. 1B and 2, the second substrate 13 can be combined with the first substrate 11 with the support columns 132 abutting against the diversion layer 12, wherein a portion of the first substrate 11 is sealed with a portion of the second substrate 13, such that the working fluid 14 can be completely sealed within the liquid passages 114. The support columns 132 facilitates the function of supporting the air flow channels 131.

In an embodiment, the first substrate 11 and the second substrate 13 can be made of metals with high thermal conductivity, such as copper, silver, aluminum, steel, titanium or alloys thereof, stainless steel, etc., and the diversion layer 12 can be made of a material with high temperature resistance, such as pure copper, copper alloy, graphite, etc., and the present disclosure is not limited as such. For example, the first substrate 11, the second substrate 13 and the diversion layer 12 can all be made of copper, and can also be formed into a mass by sintering.

When the vapor chamber 1 of the present disclosure is in use, as shown in FIG. 2, the working fluid 14 is vaporized in the evaporation area 111 after absorbing heat from the heat source 2. The vaporized working fluid 142 then reaches the air flow channels 131 through the first openings 121 corresponding to the evaporation area 111, and moves along the air flow channels 131 to the condensation area 112. Thereafter, the vaporized working fluid 142 condenses (waiting to be cooled) in the condensation area 112 and is liquefied on the surface of the diversion layer 12. The liquefied working fluid 141 is then absorbed into the first openings 121 of the diversion layer 12 at the condensation area 112 by surface tension before arriving at the liquid passages 114. From there, the working fluid 141 flows along the liquid passages 114 to the evaporation area 111 to be vaporized again. This complete one full heat dissipating circulation.

In an embodiment, depending on usage, there can be one or more condensation areas 112, and the number of evaporation areas 111 can be determined based on the number of heat sources 2 as long as there are liquid passages 114 and air flow channels 131 interconnecting the condensation area 112(s) and the evaporation area(s) 111, and the present disclosure is not limited as such.

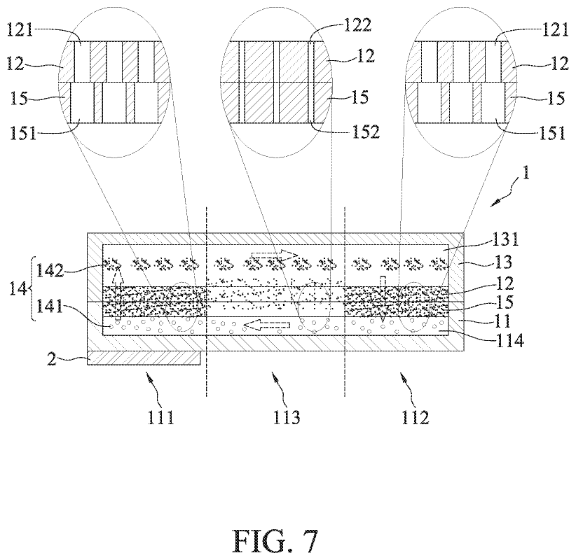

Referring to FIG. 7, the vapor chamber 1 of the present disclosure may further include at least one thin film layer 15 disposed between the diversion layer 12 and the first substrate 11. The thin film layer 15 includes a plurality of through holes 151, 152. The size of the through holes 151 corresponding to the locations of the first openings 121 is greater than the size of the corresponding first openings 121. On the other hand, the size of the through holes 152 corresponding to the locations of the second openings 122 can substantially equal to the size of the corresponding second openings 122. As such, the working fluid 14 in the evaporation area 111 can enter the larger through holes 151 before going into the relatively smaller first openings 121. This configuration facilitates capillary effect (i.e., the through holes 151 act as extension structures of the liquid passages 114 in the evaporation area 111). Similarly, after condensing and liquefying the vaporized working fluid 14 in the condensation area 112, the working fluid 14 first enters the smaller first openings 121 and then enters into the relative larger through holes 151 before finally arriving at the liquid passages 114. This configuration facilitates condensation (i.e., the through holes 151 act as extension structures of the liquid passages 114 in the condensation area 112). In an embodiment, there can be one or more thin film layer(s) 15, and the thin film layer 15 can be made of a material with high temperature resistance, such as pure copper, copper alloy, graphite, etc. The material and the thickness of the thin film layer 15 can be the same as or different from the diversion layer 12, and the present disclosure is not limited as such. In the case of a plurality of thin film layers 15, the size(s) of the through holes in the thin film layer(s) closer to the first substrate 11 is/are greater than the size(s) of the through holes in the thin film layer(s) further away from the first substrate 11. These through holes in the various thin film layers effectively form pyramid-like structures to enhance capillary effect and condensation, as well as provide support. The through holes 151, 152 can be formed by etching, laser engraving, stamping, etc., and the present disclosure is not limited as such.

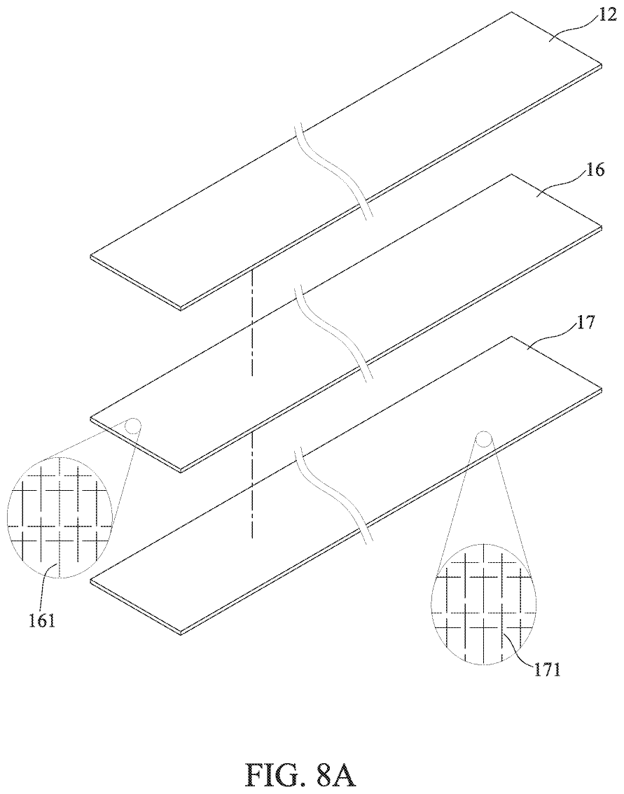

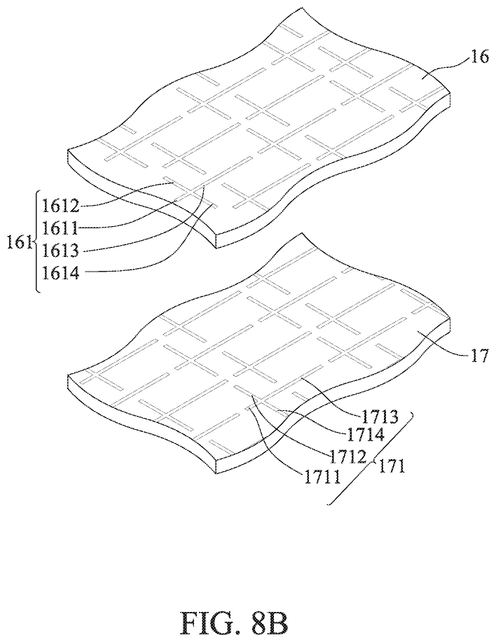

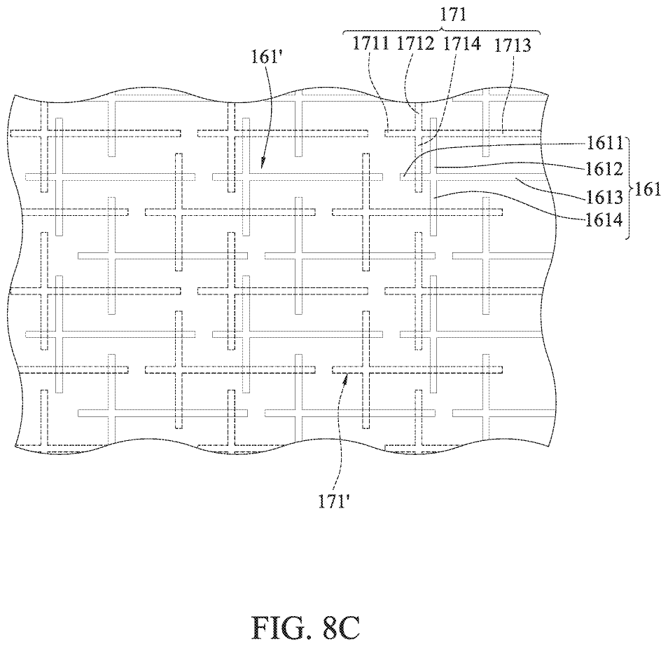

Referring to FIGS. 8A, 8B and 8C, an embodiment different from the vapor chamber 1 shown in FIG. 7 is illustrated, and only elements that are different from those of FIG. 7 are illustrated in FIG. 8A, that is, only thin film layers 16, 17 and the diversion layer 12 are illustrated. In other words, the thin film layer 15 in FIG. 7 is replaced by thin film layers 16, 17, while the rest are similar or the same to those of FIG. 7 and will not be illustrated and repeated. The number of thin film layers 16, 17 is not limited to just two, there can be three or more. The thin film layers 16, 17 can be made of materials with high temperature resistance, such as pure copper, copper alloy, graphite, etc., and the materials and thicknesses of the thin film layers 16, 17 can be the same as or different from those of the diversion layer 12; the present disclosure is not limited as such. In an embodiment, the thin film layers 16, 17 are stacked between the diversion layer 12 and the first substrate 11, and the thin film layers 16, 17 includes a plurality of through holes 161, 171, respectively. The plurality of through holes 161 penetrate through the opposite upper and lower surfaces of the thin film layer 16, and the plurality of through holes 171 penetrate through the opposite upper and lower surfaces of the thin film layer 17. The through holes 161 do not completely align or partially overlap with the through holes 171 and the first openings 121 and the second openings 122 of the diversion layer 12. More specifically, as shown in FIGS. 8B and 8C, a through hole 161 has ends 1611, 1612, 1613, 1614, and a through hole 171 has ends 1711, 1712, 1713, 1714. When a through hole 161 is described as not completely aligning or partially overlapping with a through hole 171, it means that the through hole 161 is not entirely interconnected with the through hole 171. As can be seen in FIG. 8C, only the end 1611 of a through hole 161 is partially interconnected with the end 1714 of a through hole 171, and the end 1612 of the through hole 161 is partially interconnected with the end 1713 of the through hole 171. This lengthens the paths from the liquid passages 114 to the diversion layer 12 and allows more working fluid 14 to be stored. In addition, the through hole 171 can also be interconnected with other through holes 161′, and the through holes 161 can also be interconnected with other through holes 171′. In other words, the through holes 161, 171 can be simultaneously interconnected with a plurality of other through holes to increase the paths from the liquid passages 114 to the diversion layer 12. Moreover, the through holes 161 do not completely align or partially overlap with the first openings 121 and second openings 122 of the diversion layer 12. For example, the size of the through holes 161 can be greater than the size of the first openings 121 or the second openings 122, or a single through hole 161 can simultaneously correspond to a plurality of first openings 121 or a plurality of second openings 122 (e.g., the ends 1611, 1612, 1613, 1614 of the through hole 161 can each correspond to a different first opening 121 or second opening 122), and the present disclosure is not limited as such.

In the above embodiment, the through holes 161, 171 can be formed by etching, laser engraving, stamping, or the like. The apertures of the through holes 161, 171 are greater than that of the first openings 121, and the apertures of the through holes 161, 171 can be the same, or the aperture of the through holes 171 can be greater than that of the through holes 161, and the present disclosure is not limited as such.

In the above embodiment, the through holes 161, 171 are shown in crisscross shapes, but the present disclosure is not limited to this, the through holes 161, 171 may also be triangular, star-shaped, regular polygonal or irregular polygonal.

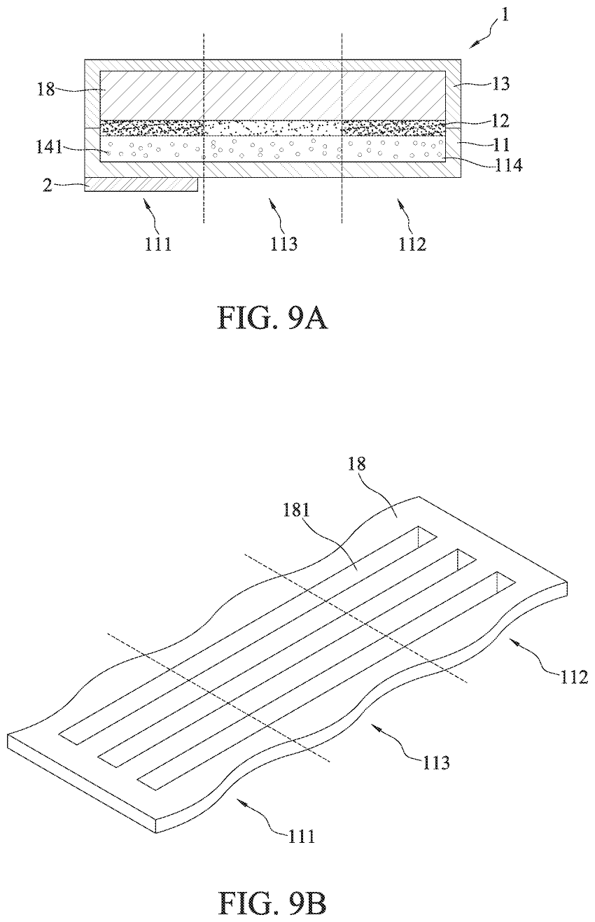

Referring to FIGS. 9A and 9B, a vapor chamber in accordance with another embodiment of the present disclosure is illustrated. The embodiment shown in FIG. 9A is roughly the same as the embodiment shown in FIG. 2, the difference is in that an additional thin film layer 18 is disposed between the diversion layer 12 and the second substrate 13, and the inner surface 133 of the second substrate 13 is no longer provided with support columns 132. As there is no support columns 132, the thin film layer 18 is in contact with the diversion layer 12 and the second substrate 13, and air flow channels 181 are provided in the thin film layer 18. As such, the thin film layer 18 provides support for the air flow channels 181. The air flow channels 181 can be formed from a particle-sintered mass, a metal mesh, grooves or a combination of the above. In an embodiment, the width of the air flow channels 181 shown in FIG. 9B may be 2 mm, and there can be a plurality of air flow channels 181 (not just limited to three channels shown in FIG. 9B).

The present disclosure is not limited to the above.

In an embodiment, there can be just one or a plurality of thin film layer(s) 18, and the present disclosure is not limited as such. In an embodiment where there are a plurality of the thin film layers 18, the air flow channels 181 can be formed from through holes in the plurality of thin film layers 18 interconnecting to one another. In addition, the vapor chamber 1 of the present disclosure from the embodiments illustrated in FIGS. 7, 8A and 9A can be used independently, or can be used simultaneously. In other words, any arbitrary combinations of the thin film layers 15, 16, 17, 18 can be provided in the vapor chamber 1, and the present disclosure is not limited to this. In addition, the diversion layer 12 and the thin film layers 15, 16, 17, 18 of the present disclosure are shown as flat sheets (thin sheets), but the present disclosure is not limited to this.

The design of the diversion layer 12 in the vapor chamber 1 described in the various embodiments of the present disclosure above allows the thickness of the vapor chamber 1 to be reduced to less than 0.25 mm, preferably less than 0.2 mm, but the present disclosure is not limited as such.

Since the diversion layer in the vapor chamber of the present disclosure is configured with openings of different sizes, working fluids can effectively flow in the liquid passages and the air flow channels separately without interfering each other. More specifically, by providing first openings with larger apertures or higher density in the evaporation area and the condensation area, vaporized or liquefied working fluids are allowed to pass through the first openings. On the other hand, providing second openings with smaller apertures or lower density in the non-evaporation area and the non-condensation area, vaporized or liquefied working fluids are prevented from passing through the second openings. As such, isolation and heat transfer efficiency can be improved, such that the non-evaporation area and the non-condensation area approximate the theoretical heat insulation area. Moreover, the diversion layer is directly disposed on the liquid passages. This not only allows grooves of a smaller size to be provided (producing greater capillary forces), but also prevents excessive amount of working fluids to be removed during a vacuum pumping stage, thereby increasing practicality.

The above embodiments are merely provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. A vapor chamber defined with an evaporation area corresponding to a heat source and at least one condensation area, the vapor chamber comprising:
a first substrate;
a diversion layer disposed on the first substrate and having a plurality of first openings and a plurality of second openings, wherein locations of the plurality of first openings correspond to the evaporation area and the condensation area, locations of the plurality of second openings do not correspond to the evaporation area and the condensation area, and a size of each of the plurality of first openings is different from a size of each of the plurality of second openings;
a plurality of liquid passages formed between the first substrate and the diversion layer; and
a second substrate disposed above the diversion layer to form air flow channels between the diversion layer and the second substrate.

2. The vapor chamber of claim 1, wherein a density of the plurality of first openings is greater than a density of the plurality of second openings.

3. The vapor chamber of claim 2, wherein a ratio of an aperture of each of the plurality of first openings to an interval between the plurality of first openings is 1:1.

4. The vapor chamber of claim 2, wherein a ratio of an aperture of each of the plurality of second openings to an interval between the plurality of second openings ranges from 1:2 to 1:4.

5. The vapor chamber of claim 1, wherein the size of each of the plurality of first openings is greater than the size of each of the plurality of second openings.

6. The vapor chamber of claim 5, wherein an aperture of each of the plurality of first openings ranges from 0.01 mm to 0.3 mm, and an aperture of each of the plurality of second openings ranges from 0.005 mm to 0.2 mm.

7. The vapor chamber of claim 1, wherein the plurality of liquid passages are a plurality of grooves recessed into a surface of the first substrate, or a particle-sintered mass, a metal mesh or a combination of the above.

8. The vapor chamber of claim 7, wherein a width of each of the plurality of grooves ranges from 0.03 mm to 0.3 mm, and wherein a depth of each of the plurality of grooves ranges from 0.01 mm to 0.15 mm.

9. The vapor chamber of claim 7, wherein the plurality of grooves are formed by wet etching.

10. The vapor chamber of claim 7, wherein the plurality of grooves have elongated, curved, square or directional shapes.

11. The vapor chamber of claim 10, wherein the directional shape includes a width of a portion corresponding to the condensation area being greater than a width of a portion corresponding to the evaporation area.

12. The vapor chamber of claim 1, wherein a thickness of the diversion layer ranges from 0.005 mm to 0.05 mm.

13. The vapor chamber of claim 1, further comprising at least one thin film layer with a plurality of through holes and disposed between the diversion layer and the first substrate, wherein a size of the plurality of through holes corresponding to the locations of the plurality of first openings is greater than the size of the corresponding plurality of first openings.

14. The vapor chamber of claim 1, further comprising a plurality of thin film layers stacked one on top of another between the first substrate and the diversion layer, wherein the plurality of thin film layers each includes a plurality of through holes, and the plurality of through holes of one of the plurality of thin film layers are not entirely in alignment with the plurality of through holes of another one of the plurality of thin film layers.

15. The vapor chamber of claim 14, wherein the plurality of through holes are crisscross-shaped, triangular, star-shaped, regular polygonal or irregular polygonal.

16. The vapor chamber of claim 1, further comprising at least one thin film layer disposed between the diversion layer and the second substrate and in contact with the diversion layer and the second substrate, wherein the air flow channels are provided within the thin film layer.

17. The vapor chamber of claim 1, further comprising a working fluid filled in the plurality of liquid passages, wherein the working fluid absorbs heat from the heat source and then vaporizes in the evaporation area, the vaporized working fluid then passes through each of the first openings corresponding to the evaporation area and moves along the air flow channels to the condensation area, the working fluid then condenses and liquefies in the condensation area, and the liquefied working fluid passes through each of the first openings corresponding to the condensation area and flows along the plurality of liquid passages to return to the evaporation area.
